(19) United States
(12) Patent Application Publication
(10) Pub. No.: US 2004/0256737 A1
(43) Pub. Date: Dec. 23, 2004

(54) [FLIP-CHIP PACKAGE SUBSTRATE AND FLIP-CHIP BONDING PROCESS THEREOF]

(76) Inventors: Min-Lung Huang, Kaohsiung (TW); Chi-Long Tsai, Kaohsiung City (TW); Chao-Fu Weng, Tainan (TW); Ching-Huei Su, Kaohsiung (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/709,923

(22) Filed: Jun. 7, 2004

(30) Foreign Application Priority Data
Jun. 20, 2003 (TW) 92116778

(51) Int. Cl. H01L 21/44; H01L 23/48

(52) U.S. Cl. 257/778; 438/108

(57) ABSTRACT

The present invention provides a flip-chip package substrate including a plurality of stacked patterned circuit layers, a plurality of dielectric layers disposed between two neighboring patterned circuit layers and a plurality of bumps. The outmost layers of the patterned circuit layers include a plurality of first contacts and a plurality of second contacts. The bumps are connected to the corresponding first contacts. Since the bumps are formed on the substrate by low-cost implanting or printing apparatuses, the production cost of the flip chip package structure is lowered and the yield of the flip chip package process is improved.

### CROSS REFERENCE TO RELATED APPLICATIONS

This application claims the priority benefit of Taiwan application serial no. 92116778, filed Jun. 20, 2003.

### BACKGROUND OF INVENTION

1. Field of Invention

The present invention relates to a package substrate. More particularly, the present invention relates to a package substrate for flip chips.

2. Description of Related Art

In recent year, as the electronic technologies improves in fast speed, the advanced electronic devices have to meet requirements of multiple-functions and user friendliness and develop toward miniaturization, lightweight, and low cost. In the integrated circuit packaging processes, the substrate type carrier is one of the commonly used package mediums. The substrate type carrier in general can be classified as the laminated substrate and the build-up substrate. The substrate is composed of a plurality of patterned circuit layers and a plurality of insulation layers, arranged alternatively. The surface of the substrate includes a plurality of contacts, for connecting chips or inputting/outputting to the external circuitry.

Flip chip interconnect technology has become widely used nowadays, because the flip chip package provides high-density pitch, compact size and high electrical performance. The bare dies (chips) dicing from the wafer are flipped (i.e. flip chip) and arranged onto the substrate. Bumps are formed on the bonding pads of the die. The bumps are connected to the contacts of the substrate, so that the bonding pads of the die are electrically connected to the contacts of the substrate. Later on, an underfill process is performed to fill an underfill material between the substrate and the bare die. The underfill material can protect the exposed portions of the bumps and act as a buffer for the thermal coefficient of expansion (TCE) mismatch between the chip and the package medium.

FIGS. 1-3 are cross-sectional display views illustrating a conventional fabrication process for flip chip package structure. Referring to the FIG. 1, a substrate 100 is provided. The substrate 100 is a laminated substrate or a build up substrate, for example. The surfaces of the substrate 100 includes a plurality of first contacts 110 on the first surface 102 of the substrate 100 and a plurality of second contacts 112 on the second surface 104 of the substrate 100. The first contacts 110 and the second contacts 112 are formed from the outermost layers of the patterned circuit layers 106 of the substrate 100. One insulation layer 108 is arranged between every two adjacent patterned circuit layers 106, while the adjacent patterned circuit layers 106 can be electrically connected to one another by way of plated through-holes 108a or vias 108b in the insulation layer 108. Two solder mask layer 114, 116 are formed on the first and second surfaces 102, 104 respectively by, for example, spin-coating, while the first and second contacts 110, 112 are exposed by the solder mask layers 114, 116.

As shown in FIG. 2, a chip 120 is arranged onto the substrate 100 by flip chip technology. The chip 120 includes a plurality of bonding pads 122 and a plurality of bumps 126 attached on the surfaces of the bonding pads 122. The bumps 126 of the chip 120 are connected to the first contacts 110 of the substrate 100. In the prior art, before forming bumps 126 on the bonding pads 122, an under bump metallurgy (UBM) layer 124, acting as an interface, is formed by evaporation or sputtering, between the bumps 126 and the bonding pads 122.

The fabrication of the UBM layer is quite complicated, and the UBM layer 124 is composed of multiple-layered metal materials, including an adhesion layer, a barrier layer, and a wetting layer. The materials of the UBM layer 124 include titanium, tungsten, nickel, gold, copper and alloys thereof. The UBM layer 124 can prevent the Sn/Pb bumps 126 peeling from the bonding pads 122 of the chip 120.

Referring to FIG. 3, the bumps 126 are reflowed and an underfill material (not shown) is filled between the chip 120 and the substrate 100, thus completing a flip chip package structure.

It is noted that the chip requires forming the UBM layer on the bonding pads and then forming the bumps on the UBM layer, in the prior art flip chip package structure. Since the fabrication process is complex and the processing systems are expensive, the production yield of the flip chip package structure is not satisfactory and the production cost according to the prior art fabrication process is uneconomical. Furthermore, several reflow steps are required to form the bumps on the chip and one extra reflow step is needed to connect the bumps to the substrate, thus lowering the reliability of the bumps and the quality of the package structure.

### SUMMARY OF INVENTION

The present invention provides a flip chip package substrate, applied in the flip chip package structure, which simplifies the fabrication process of the UBM layer and lowers the production cost for the chip package.

The present invention provides a flip chip package process by arranging bumps on the substrate, enhancing the yield of the chip package.

As embodied and broadly described herein, the flip chip package substrate of the present invention, comprises a plurality of patterned circuit layers including a plurality of first contacts and a plurality of second contacts, a plurality of dielectric layers, each dielectric layer being disposed between any two adjacent patterned circuit layers, and the patterned circuit layers and the dielectric layers being arranged alternatively, and a plurality of bumps, disposed on the first surface of the flip chip package substrate, each bump being connected to one corresponding first contact. The bumps of the flip chip package substrate are connected to a chip, and electrically connect the chip and the flip chip package substrate.

As embodied and broadly described herein, the present invention provides a flip chip package process, comprising the following steps. A substrate having a first surface and an opposite second surface is provided, including a plurality of first contacts on the first surface of the substrate and a plurality of second contacts on the second surface of the substrate. A plurality of bumps is formed on the first surface of the substrate, while each bump is connected to one first contact. A chip having a plurality of bonding pads corresponding to the bumps is provided, with a metal layer disposed on surfaces of the bonding pads. The chip is flipped and arranged onto the first surface of the substrate, so that the bonding pads are connected to the bumps. The bumps are then reflowed.

In the present invention, the bonding pads of the chip are electrically connected to the substrate through the bumps on the substrate, so that the fabrication process of the flip chip package structure is simplified and the production yield is increased. Furthermore, several reflow steps are skipped for the formation of the bumps, thus increasing the reliability of the bumps and the quality of the package structure.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1-3 are cross-sectional display views illustrating a conventional fabrication process for flip chip package structure.

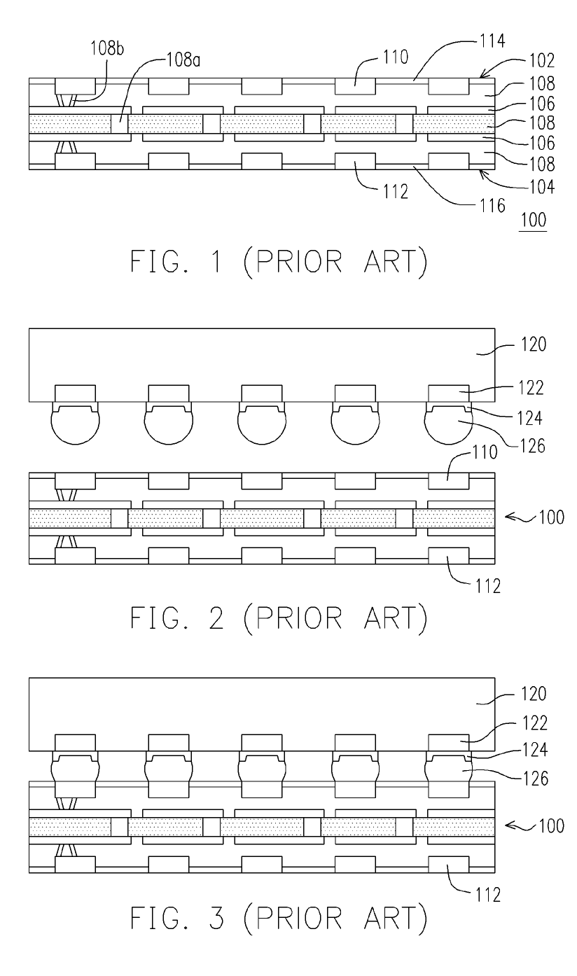

FIGS. 4-6 are cross-sectional display views illustrating a fabrication process for flip chip package structure according to one preferred embodiment of this invention.

FIG. 7 is a cross-sectional display view illustrating a fabrication process step for flip chip package structure according to another preferred embodiment of this invention.

### DETAILED DESCRIPTION

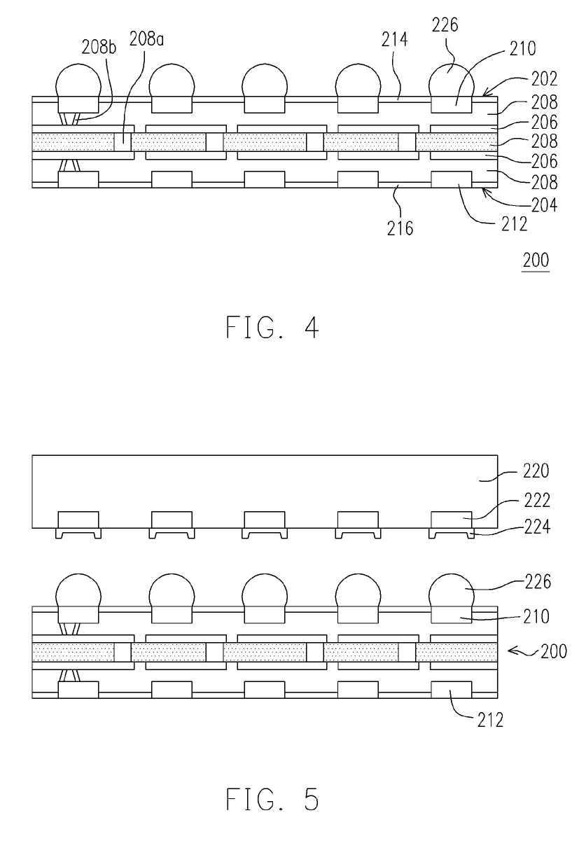

FIGS. 4-6 are cross-sectional display views illustrating a fabrication process for flip chip package structure according to one preferred embodiment of this invention. Referring to the FIG. 4, a substrate 200 is provided. The substrate 200 is a laminated substrate or a build up substrate, for example. The surfaces of the substrate 200 includes a plurality of first contacts 210 on the first surface 202 of the substrate 100 and a plurality of second contacts 212 on the second surface 204 of the substrate 200. The first contacts 210 and the second contacts 212 are formed from the two outermost layers of the patterned circuit layers 206 of the substrate 200. The first and second contacts 210, 212 are electrically connected. One insulation layer 208 is arranged between every two adjacent patterned circuit layers 206, while the adjacent patterned circuit layers 206 can be electrically connected to one another by way of plated through-holes 208a or vias 208b in the insulation layer 208. A first solder mask layer 214 and a second solder mask layer 216 are formed on the first surface 202 and the second surface 204 respectively by, for example, spin-coating or affixture, while the first and second contacts 210, 212 are exposed by the solder mask layers 214, 216.

It is emphasized that a plurality of bumps 226 are disposed on the first surface 202 of the substrate 200 and correspondingly connected to the first contacts 210, before arranging the chip onto the substrate 200 (i.e. the flipping chip step).

According to the preferred embodiment, bumps 226, such as, Sn/Pb bumps or other high melting point bumps, are formed on the surfaces of the first contacts 210. The bump 226 is formed by, for example, implanting globular tin globes onto the surface of the first contact 210. In addition, the surface of the first contact 210 can be treated with a flux (not shown) before implanting the bump. The flux can help momentarily fixing the bump 226 onto the first contact 210 and activate the oxides on the surface of the bump 226 in the high temperature reflow process for better attachment. Alternatively, the bump 226 is formed by, for example, stencil printing the low melting temperature tin paste to the surface of the first contact 210 and performing a reflow step to obtain globular bump. Alternatively, the bump 226 can be directly formed by electroplating during the fabrication process of the package substrate, without the reflow step.

As shown in FIG. 5, a chip 220 is arranged onto the substrate 200. The chip 220 includes a plurality of bonding pads 222, corresponding to the bumps 226 on the surfaces of the substrate 200. A metal layer 224 is formed in the surface of the bonding pad 222 by electroless plating, for example. For example, the metal layer 224 is a nickel/gold (Ni/Au) layer or is made of metals selected from the following group consisting of nickel, gold, titanium, copper and palladium. If a nickel layer is formed, the nickel layer can act as a barrier layer between the bonding pad 222 and the bump 226. Above the nickel layer, the gold or copper layer can protects nickel from oxidation and act as a wetting layer for increasing attachment between the bonding pad 222 and the bump 226.

In FIG. 6, the chip 220 is arranged onto the first surface 202 of the substrate 200 by flip chip bonding. The bonding pads 222 of the chip 220 are connected to the bumps 226 on the substrate 200, and the bumps 226 are connected to the corresponding first contacts 210. The bumps 226 are reflowed and firmly attached to the bonding pads 222, thus electrically connecting the chip 220 and the substrate 200. Optionally, an underfill material (not shown) is filled between the chip 220 and the substrate 200, thus completing a flip chip package structure.

In addition, on the second surface 204 of the substrate 200, a plurality of solder balls (not shown) or pins (not shown) can be arranged to connect the corresponding second contacts 212, thereby forming a flip chip package structure in ball grid array (BGA) or pin grid array (PGA).

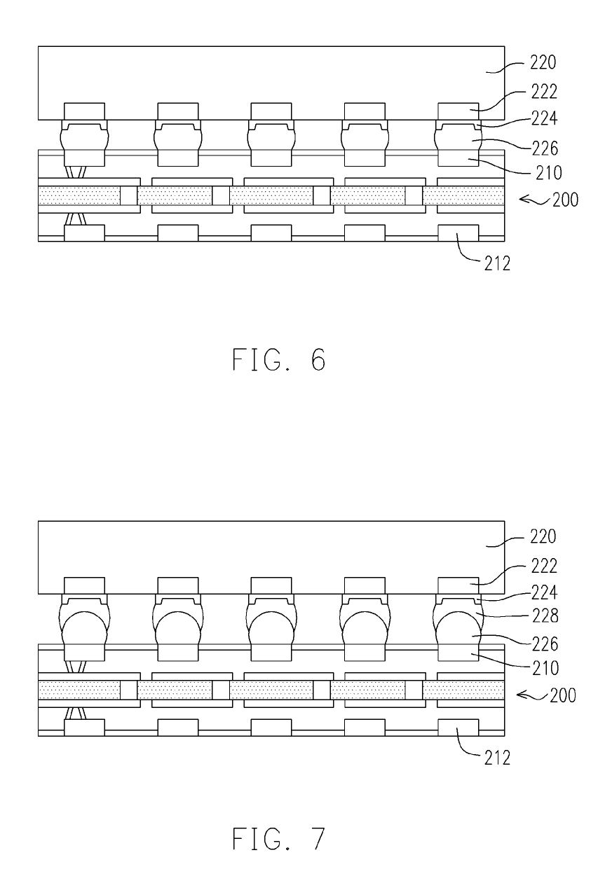

Referring to FIG. 7, illustrating the process step for the flip chip package structure according to another preferred embodiment of this invention. Before, the flipping chip step, an adhesive layer 228 is formed on the surface of the bonding pad 222 of the chip 220. After arranging the chip 220 onto the substrate 200 and after the reflow step, the low melting point adhesive layer 228 melts and wraps around the high melting point bumps 226.

In the present invention, the bumps that are arranged on the surface of the substrate can be formed by low-cost implanting or printing process, thus reducing the production cost of the flip chip package. Moreover, the bonding pads of the chip are electrically connected to the substrate through the bumps on the substrate, so that the fabrication process of the flip chip package structure is simplified and the production yield is increased.

Furthermore, the bumps can be formed by plating during the fabrication process of the substrate, so that several reflow steps are skipped for the formation of the bumps, thus increasing the reliability of the bumps and the quality of the package structure.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A flip chip package substrate, comprising:
a plurality of patterned circuit layers, wherein two outmost layers of the patterned circuit layers form a plurality of first contacts on a first surface of the flip chip package substrate and form a plurality of second contacts on a second surface of the flip chip package substrate, and wherein the first contacts are electrically connected to the second contacts;
a plurality of dielectric layers, each dielectric layer being disposed between any two adjacent patterned circuit layers, wherein the patterned circuit layers and the dielectric layers are arranged alternatively; and
a plurality of bumps, disposed on the first surface of the flip chip package substrate, wherein each bump is connected to one corresponding first contact, and wherein the bumps are to be connected to a chip.

2. The substrate of claim 1, further comprising a plurality of solder balls disposed on the second surface of the flip chip package substrate, wherein the solder balls connect to the second contacts.

3. The substrate of claim 1, further comprising a plurality of pins disposed on the second surface of the flip chip package substrate, wherein the pins connect to the second contacts.

4. The substrate of claim 1, wherein two solder mask layers are respectively arranged on the first and second surfaces of the flip chip package substrate, while the first and second contacts are exposed by the two solder mask layers.

5. The substrate of claim 1, wherein a material of the bumps includes tin/lead alloy.

6. A flip chip package process, comprising:
providing a substrate having a first surface and an opposite second surface, wherein the substrate includes a plurality of first contacts on the first surface of the substrate and a plurality of second contacts on the second surface of the substrate, and wherein the first contacts are electrically connected to the second contacts;
forming a plurality of bumps on the first surface of the substrate, wherein each bump is connected to one first contact;
providing a chip having a plurality of bonding pads corresponding to the bumps, wherein a metal layer is disposed on surfaces of the bonding pads;
arranging the chip onto the first surface of the substrate by flipping the chip, so that the bonding pads are connected to the bumps; and
reflowing the bumps.

7. The process of claim 6, further comprising disposing a plurality of solder balls on the second surface of the substrate, wherein the solder balls are connected to the second contacts.

8. The process of claim 6, further comprising disposing a plurality of pins on the second surface of the substrate, wherein the pins are connected to the second contacts.

9. The process of claim 6, wherein the method for forming the bumps comprises implanting tin globes and treating surfaces of the first contacts with a flux before implanting the tin globes.

10. The process of claim 6, wherein the method for forming the bumps comprises printing a tin paste onto surfaces of the first contacts and reflowing the tin paste.

11. The process of claim 6, wherein the method for forming the bumps comprises forming the bumps on surfaces of the first contacts by electroplating, thus forming the bumps on the substrate without reflowing.

12. The process of claim 6, wherein an adhesive layer is formed on the surfaces of the bonding pads of the chip before the chip is arranged to the substrate, and wherein after the chip is arranged to the substrate, the adhesive layer wraps around the bumps.

13. The process of claim 6, further comprising filling an underfill material between the chip and the substrate, wherein the underfill material covers the bumps.

14. The process of claim 6, wherein the metal layer is a nickel layer formed by electroless plating.
